(19) United States
(12) Patent Application Publication
(10) Pub. No.: US 2018/0361422 A1
(43) Pub. Date: Dec. 20, 2018

(54) SPIN-ON-DIELECTRIC PROCESS

(71) Applicants: UNITED MICROELECTRONICS CORP., Hsin-Chu City (TW); Fujian Jinhua Integrated Circuit Co., Ltd., Quanzhou City (CN)

(72) Inventors: Jui-Min Lee, Taichung City (TW); Ching-Hsiang Chang, Tainan City (TW); Cheng-Hsu Huang, New Taipei City (TW); Yi-Wei Chen, Taichung City (TW); Wei-Hsin Liu, Changhua County (TW); Shih-Fang Tzou, Tainan City (TW)

(21) Appl. No.: 15/939,305

(22) Filed: Mar. 29, 2018

(30) Foreign Application Priority Data
Jun. 16, 2017 (CN) 201710455942.2

(51) Int. Cl. B05D 1/00; B05C 11/08; H01L 21/02; H01L 21/762

(52) U.S. Cl. CPC B05D 1/005; H01L 21/76224; H01L 21/02282; B05C 11/08

(57) ABSTRACT

A spin-on-dielectric process includes the following steps. A substrate is provided. A flowable material is spread on a surface of the substrate to forma spin-on-dielectric layer on the substrate, wherein the flowable material is heated to a temperature higher than 25° C.

### BACKGROUND OF THE INVENTION

### 1. Field of the Invention

The present invention relates generally to a coating process, and more specifically to a spin-on-dielectric (SOD) process.

### 2. Description of the Prior Art

Dielectric materials are often deposited by spin-on dielectric (SOD) process or chemical vapor deposition (CVD) process. While using the spin-on dielectric (SOD) process, a flowable dielectric material can be coated into gaps in a substrate easily through adjusting dibasic ester (DBE) system. This is an unique advantage of the spin-on dielectric (SOD) process, and thus the spin-on dielectric (SOD) process is widely used in nowadays industry.

Trenches with different sizes are usually formed in a substrate. A dielectric material covers the surface of the trenches while coating the dielectric material on the substrate by the spin-on dielectric (SOD) process. However, voids may occur in the films transformed by the dielectric material, which usually occurs at the bottom of the trenches. Thus, it becomes a challenge to eliminate the voids in the films.

### SUMMARY OF THE INVENTION

The present invention provides a spin-on-dielectric process, which heats a flowable material spread during a spin-on-dielectric process for forming a dielectric, thereby increasing the fluidity of the flowable material and improving the gap filling capability of the flowable material.

The present invention provides a spin-on-dielectric process including the following steps. A substrate is provided. A flowable material is spread on a surface of the substrate to form a spin-on-dielectric layer on the substrate, wherein the flowable material is heated to a temperature higher than 25° C.

According to the above, the present invention provides a spin-on-dielectric process, which heats a flowable material while spread it on a surface of a substrate, especially for heating the flowable material to a temperature higher than 25° C., to form a spin-on-dielectric layer on the substrate. By doing this, the viscosity of the flowable material is reduced, the fluidity of the flowable material is increased and the gap filling capability of the flowable material is improved. Hence, voids in the formed spin-on-dielectric layer can be avoided.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 schematically depicts a cross-sectional view of an improved spin-on-dielectric process according to an embodiment of the present invention.

FIG. 2 schematically depicts a cross-sectional view of an improved spin-on-dielectric process according to an embodiment of the present invention.

FIG. 3 schematically depicts a cross-sectional view of an improved spin-on-dielectric process according to an embodiment of the present invention.

FIG. 4 schematically depicts an apparatus of an improved spin-on-dielectric process according to an embodiment of the present invention.

FIG. 5 schematically depicts a cross-sectional view of an improved spin-on-dielectric process according to another embodiment of the present invention.

FIG. 6 schematically depicts a cross-sectional view of an improved spin-on-dielectric process according to another embodiment of the present invention.

FIG. 7 schematically depicts a cross-sectional view of an improved spin-on-dielectric process according to another embodiment of the present invention.

FIG. 8 schematically depicts a cross-sectional view of an improved spin-on-dielectric process according to another embodiment of the present invention.

FIG. 9 schematically depicts a cross-sectional view of an improved spin-on-dielectric process according to another embodiment of the present invention.

### DETAILED DESCRIPTION

FIGS. 1-3 schematically depict cross-sectional views of an improved spin-on-dielectric process according to an embodiment of the present invention. As shown in FIG. 1, a substrate 110 is provided. The substrate 110 may be a semiconductor substrate such as a silicon substrate, a silicon containing substrate, a III-V group-on-silicon (such as GaN-on-silicon) substrate, a graphene-on-silicon substrate or a silicon-on-insulator (SOI) substrate. The substrate 110 may be divided into a first area A1, a second area A2 and a third area B. For instance, the first area A1 and the second area A2 may be memory cell areas while the third area B may be a peripheral area, wherein circuits in the peripheral area are used to operate memory cells in the memory cell areas, but it is not limited thereto. In this embodiment, a plurality of memory cells are disposed in each of the memory cell areas, to forma dynamic random access memory (DRAM) device having recessed gate structures, but it is not limited thereto.

A plurality of trenches R1/R2/R3 are formed in the substrate 110, wherein methods of forming the trenches R1/R2/R3 may include the following, but it is not restricted thereto. A pad oxide layer (not shown) and a pad nitride layer (not shown) are formed blanketly and sequentially on the substrate 110, and the pad nitride layer and the pad oxide layer are patterned to form a pad oxide layer 2 and a pad nitride layer 4, thereby areas of the substrate 110 for forming the trenches R1/R2/R3 being exposed. The substrate 110 is then etched to form the trenches R1/R2/R3 . In this case, the plurality of trenches R1 are formed in the first area A1 of the substrate 110, the plurality of trenches R2 are formed in the second area A2 of the substrate 110, and the trench R3 is formed in the third area B of the substrate 110. There are six trenches R1, three trenches R2 and one trench R3 depicted in the figures, but the numbers of the trenches R1, the trenches R2 and the trench R3 are not restricted thereto. A width W1 of each of the trenches R1 is smaller than a width W2 of each of the trenches R2, and the width W2 of each of the trenches R2 is smaller than a width W3 of the trench R3. The widths W1/W2/W3 depend upon sizes of devices requiring to be isolated.

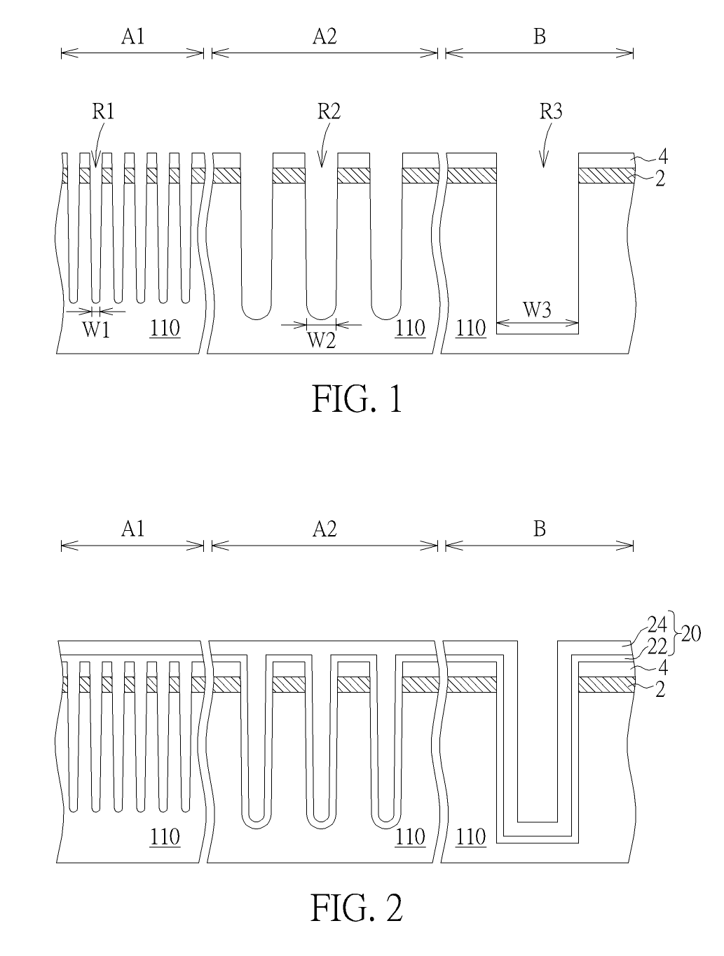

As shown in FIG. 2, a liner 20 is optionally formed on the substrate 110. In an embodiment, the liner 20 may be an oxide liner or/and an oxynitride liner, but it is not limited thereto. The liner 20 maybe composed of other materials instead. In this case, the liner 20 may include an oxide liner 22 and an oxynitride liner 24 stacked from bottom to top, and the oxide liner 22 and the oxynitride liner 24 may be formed by an atomic layer deposition (ALD) processes, but it is not limited thereto. In this embodiment, the oxide liner 22 fills up the trenches R1 of the first area A1 and partially covers the trenches R2 of the second area A2 and the trench R3 of the third area B. The oxynitride liner 24 fills up the trenches R2 of the second area A2 and partially covers the trench R3 of the third area B.

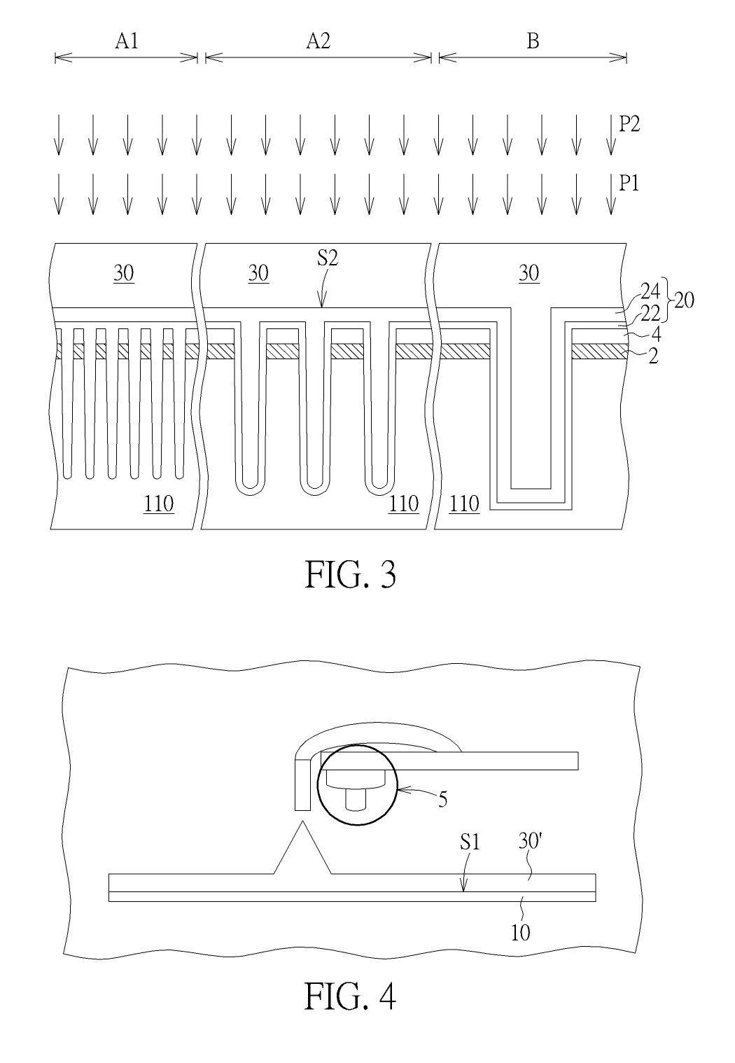

As shown in FIG. 3, a pre-cleaning process (not shown) is optionally performed to remove particles remaining in the trenches R1/R2/R3. The pre-cleaning process may include a high pressure cleaning process, but it is not limited thereto. A spin-on-dielectric layer 30 is formed on the substrate 110. Methods of forming the spin-on-dielectric layer 30 may include a spin-on-dielectric process P1, but it is not limited thereto. The method of performing the spin-on-dielectric process P1 is shown in FIG. 4. A flowable material 30′ is spread on a surface S1 of a substrate 10. The substrate 10 may be the substrate 110 of FIG. 3 or the substrate 110 and the liner 20 of FIG. 3. In this case, the substrate 10 include the substrate 110 and the liner 20, therefore the surface S1 of the substrate 10 represents a surface S2 of the liner 20 in FIG. 3.

It is emphasized that, the flowable material 30′ is heated while is spread on the surface S1 of the substrate 10. Methods of heating the flowable material 30′ may include heating the surface S1 of the substrate 10 directly or heating a nozzle 5 spreading the flowable material 30′. In another case, the surface S1 of the substrate 10 and the nozzle 5 spreading the flowable material 30′ are heated at the same time, depending upon requirements.

Preferably, the flowable material 30′ is heated to a temperature higher than 25° C. while the flowable material 30′ is spread on the surface S1 of the substrate 110. By doing this, the viscosity of the flowable material 30′ is reduced, the fluidity of the flowable material 30′ is increased, thereby improving the gap filling capability of the flowable material 30′ to avoid voids in the spin-on-dielectric layer 30. In a preferred embodiment, the flowable material 30′ is heated to a temperature of 30° C.-100° C. while the flowable material 30′ is spread on the surface S1 of the substrate 110. In a still preferred embodiment, the flowable material 30′ is heated to a temperature of 30° C.-40° C. while the flowable material 30′ is spread on the surface S1 of the substrate 110. Since the viscosity of the flowable material 30′ decreases in a temperature range but increases higher than this temperature range, the viscosity of the flowable material 30′ decreases without solidification while the flowable material 30′ is heated in a temperature of 30° C.-100° C. Furthermore, while the flowable material 30′ is heated in a temperature of 30° C.-40° C., processing efficiency can be increased and processing costs can be reduced.

The fluidity of a solute of the flowable material 30′ is increased, or/and the viscosity of a solvent of the flowable material 30′ is reduced while the flowable material 30′ is heated, thereby improving the gap filling capability of the flowable material 30′, and avoiding voids in the spin-on-dielectric layer 30. The solute of the flowable material 30′ may include polysilazane (PSZ, SiH₂NH), but it is not limited thereto. The solvent of the flowable material 30′ may include aromatic hydrocarbons, aliphatic hydrocarbons or ether-type solvents, but it is not limited thereto. The flowable material 30′ can be constituted by the solute and the solvent, but it is not limited thereto.

Please refer to FIG. 3, a curing process P2 is performed to cure the flowable material 30′ of FIG. 4, thereby the spin-on-dielectric layer 30 can being formed on the surface S2 of the liner 20. The curing process P2 may include an annealing process, but it is not limited thereto. Thereafter, a chemical mechanical polishing (CMP) process may be performed to planarize the spin-on-dielectric layer 30, the oxynitride liner 24 and the oxide liner 22 until the pad nitride layer 4 being exposed.

According to the above, the improved spin-on-dielectric process of the present invention is applied to form isolation structures isolating the Dynamic Random Access Memory (DRAM) cells having recessed gate structures from each other.

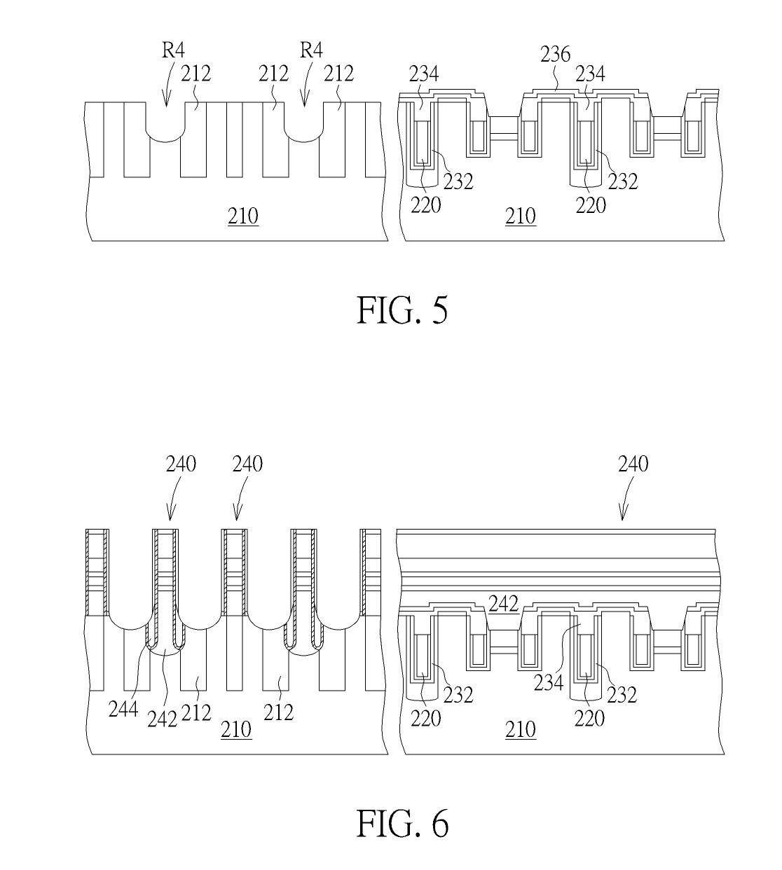

Another embodiment applying the present invention to form an interdielectric layer of a dynamic random access memory (DRAM) device having recessed gate structures is presented, but the present invention can also be applied in other layers of the dynamic random access memory (DRAM) device. FIGS. 5-9 schematically depict cross-sectional views of an improved spin-on-dielectric process according to another embodiment of the present invention. FIGS. 5-9 include left diagrams and right diagrams orthogonal to the left diagrams. As shown in FIG. 5, the substrate 210 may include isolation structures 212. In this embodiment, the isolation structures 212 may be shallow trench isolation structures, but it is not limited thereto. The isolation structures 212 may be formed by the improved spin-on-dielectric process as shown in FIGS. 1-4.

A plurality of embedded word lines 220 are disposed in the substrate 210 and trenches R4 are formed in the substrate 210 for forming bit line contacts in later processes. Isolation materials covering a surface of the substrate 210 may include a plurality of silicon oxide layers 232, silicon nitride layers 234, silicon oxide layers 236 and etc, but it is not limited thereto.

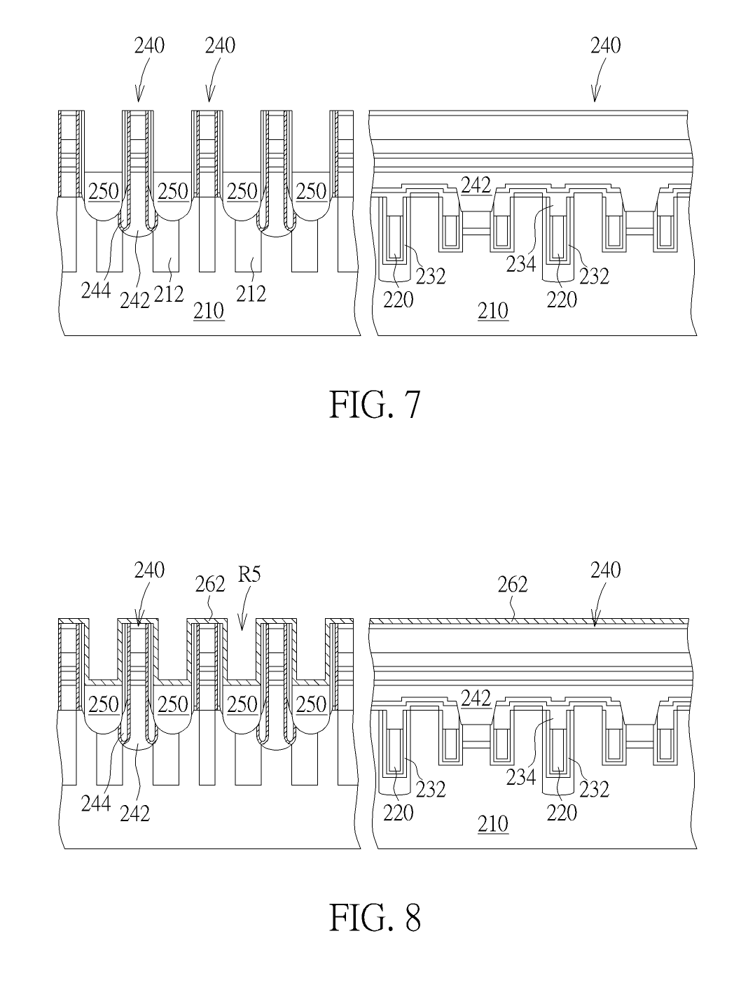

As shown in FIG. 6, bit line gates 240 are formed on the trenches R4 of the substrate 210, wherein the bit line gates 240 are preferably disposed on the substrate 210 and cover the embedded word lines 220 in the substrate 210. Methods of forming the bit line gates 240 may include blanketly staking material layers (not shown) on the substrate 210, wherein the material layers may include an amorphous silicon layer and a metal stacked structure stacked from bottom to top, but it is not limited thereto. The metal stacked structure may include a titanium layer, a titanium nitride layer, a first tungsten nitride layer and a tungsten layer stacked from bottom to top. Then, the material layers may be patterned to form the bit line gates 240, and bit line contacts 242 are in bottoms of the bit line gates 240. Spacers 244 are formed at two sides of the bit line gates 240. The spacers 244 may include nitride spacers, but it is not limited thereto. In this way, the bit line gates 240 including the bit line contacts 242 at the bottoms are formed. That is, the bit line gates 240 and the bit line contacts 242 are one piece, and may be formed by one same silicon layer.

As shown in FIG. 7, storage node contacts 250 are formed in the substrate 210 beside the bit line contacts 242. Methods of forming the storage node contacts 250 may include etching the substrate 210 to form trenches beside the bit line contacts 242, and then forming the storage node contacts 250 in the trenches, but it is not limited thereto.

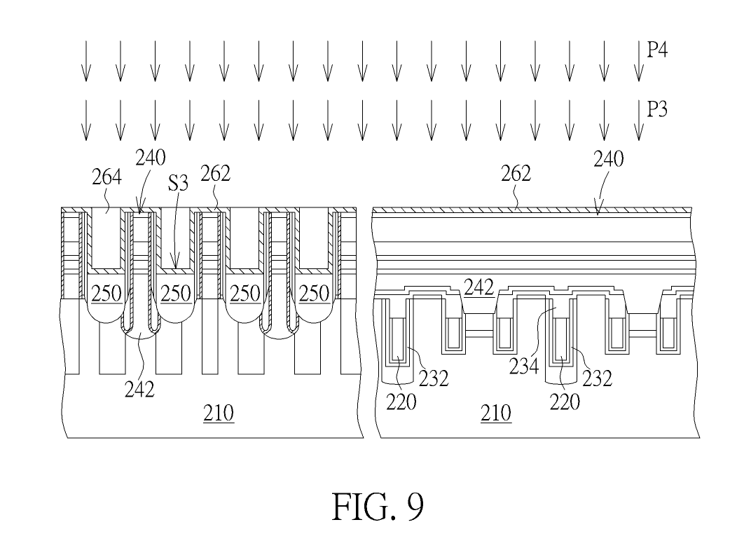

As shown in FIG. 8, a liner 262 is optionally formed to cover the substrate 210, the bit line gates 240 and the storage node contacts 250. The liner 262 may include an oxide liner or/and an oxynitride liner, or the liner 262 maybe composed of other materials, and these material layers may be deposited by atomic layer deposition (ALD) processes. Trenches R5 are formed above on the storage node contacts 250 and between the bit line contacts 242.

As shown in FIG. 9, a pre-cleaning process (not shown) is optionally performed to remove remaining particles in the trenches R5. The pre-cleaning process may include a high pressure cleaning process, but it is not limited thereto. A spin-on-dielectric layer 264 is formed on the substrate 210. Methods of forming the spin-on-dielectric layer 264 may include performing a spin-on-dielectric process P3, but it is not limited thereto. Methods of forming the spin-on-dielectric layer 264 may include the step of FIG. 4, meaning spreading the flowable material 30′ on the surface S1 of the substrate 10. The substrate 10 may be the substrate 210 of FIG. 9 or may be the substrate 210 and the liner 262 of FIG. 9. In this embodiment, the substrate 10 may include the substrate 210 and the liner 262, so that the surface S1 of the substrate 10 represents a surface S3 of the liner 262 as shown in FIG. 9.

As the flowable material 30′ is spread on the surface S1 of the substrate 10, the flowable material 30′ is heated as well. Methods of heating the flowable material 30′ may include heating the surface S1 of the substrate 10 directly, or heating the nozzle 5 for spreading the flowable material 30′. In another embodiment, the surface S1 of the substrate 10 and the nozzle 5 for spreading the flowable material 30′ are heated at the same time, depending upon practical requirements.

In a preferred embodiment, the flowable material 30′ is heated to a temperature higher than 25° C. as the flowable material 30′ is spread on the surface S1 of the substrate 10. This can decrease the viscosity of the flowable material 30′, increases the fluidity of the flowable material 30′ and improves the gap filling capability of the flowable material 30′ to prevent the spin-on-dielectric layer 264 from having voids therein. In a still preferred embodiment, the flowable material 30′ is heated to a temperature of 30° C.-100° C. as the flowable material 30′ is spread on the surface S1 of the substrate 10. Preferably, the flowable material 30′ is heated to a temperature of 30° C.-40° C. as the flowable material 30′ is spread on the surface S1 of the substrate 10. The viscosity of the flowable material 30′ decreases gradiently in a temperature range, but the flowable material 30′ solidifies beyond the temperature range. Therefore, as the flowable material 30′ is heated to a temperature of 30° C.-100° C., the viscosity of the flowable material 30′ is decreased without solidified. As the flowable material 30′ is heated to a temperature of 30° C.-40° C., process efficiency is improved and processing cost is reduced.

More precisely, the fluidity of a solute of the flowable material 30′ is increased, or/and the viscosity of a solvent of flowable material 30′ is reduced as the flowable material is heated, thereby the gap filling capability of the flowable material 30′ can being improved to avoid voids in the spin-on-dielectric layer 264. The solute of the flowable material 30′ may include polysilazane (PSZ, SiH₂NH), and the solvent of the flowable material 30′ may include aromatic hydrocarbons, aliphatic hydrocarbons or ether-type solvents, but it is not limited thereto. The flowable material 30′ can be constituted by the solute and the solvent, but it is not limited thereto.

As shown in FIG. 9, a curing process P4 may be performed to cure the flowable material 30′ of FIG. 4, to form the spin-on-dielectric layer 264 on the surface S3 of the liner 262. The curing process P4 may be an annealing process, but it is not limited thereto. Thereafter, a planarization process such as a chemical mechanical polishing (CMP) process may be performed to planarize the spin-on-dielectric layer 264 until the liner 262 being exposed.

To summarize, the present invention provides a spin-on-dielectric process, which heats a flowable material while spread it on a surface of a substrate, especially for heating the flowable material to a temperature higher than 25° C., to form a spin-on-dielectric layer on the substrate. By doing this, the viscosity of the flowable material is reduced, the fluidity of the flowable material is increased and the gap filling capability of the flowable material is improved. Hence, voids can be avoided in the formed spin-on-dielectric layer.

In a preferred embodiment, the flowable material is heated to a temperature of 30° C.-100° C. to reduce the viscosity of the flowable material and prevent the flowable material from being solidified. In a still preferred embodiment, the flowable material is heated to a temperature of 30° C.-40° C. to improve processing efficiency and reduce processing cost.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A spin-on-dielectric process, comprising:
providing a substrate; and
spreading a flowable material on a surface of the substrate to form a spin-on-dielectric layer on the substrate, wherein the flowable material is heated to a temperature higher than 25° C.

2. The spin-on-dielectric process according to claim 1, wherein the flowable material is heated by heating the surface of the substrate.

3. The spin-on-dielectric process according to claim 1, wherein the flowable material is heated by heating a nozzle of spreading the flowable material.

4. The spin-on-dielectric process according to claim 1, wherein the spin-on-dielectric layer is formed by a spin-on-coating process.

5. The spin-on-dielectric process according to claim 1, wherein the flowable material is heated to reduce the viscosity of the flowable material.

6. The spin-on-dielectric process according to claim 1, wherein the flowable material is heated to increase the fluidity of a solute of the flowable material.

7. The spin-on-dielectric process according to claim 6, wherein the solute of the flowable material comprises polysilazane (PSZ, SiH₂NH).

8. The spin-on-dielectric process according to claim 1, wherein the flowable material is heated to reduce the viscosity of a solvent of the flowable material.

9. The spin-on-dielectric process according to claim 8, wherein the solvent of the flowable material comprises aromatic hydrocarbons, aliphatic hydrocarbons or ether-type solvents.

10. The spin-on-dielectric process according to claim 1, further comprising:
forming a trench in the substrate before spreading the flowable material.

11. The spin-on-dielectric process according to claim 1, further comprising:
forming an opening in a dielectric layer, and the dielectric layer located on the substrate before spreading the flowable material.

12. The spin-on-dielectric process according to claim 1, further comprising:
forming a liner on the substrate before spreading the flowable material.

13. The spin-on-dielectric process according to claim 12, wherein the liner comprises an oxide liner or/and an oxynitride liner.

14. The spin-on-dielectric process according to claim 12, wherein the liner comprises the oxide liner and the oxynitride liner stacked from bottom to top.

15. The spin-on-dielectric process according to claim 1, wherein the flowable material is heated to a temperature of 30° C.-100° C.

16. The spin-on-dielectric process according to claim 15, wherein the flowable material is heated to a temperature of 30° C.-40° C.
